(19) United States
(12) Patent Application Publication
(10) Pub. No.: US 2007/0079192 A1
(43) Pub. Date: Apr. 5, 2007

(54) Scan driver and organic light emitting display device having the same

(76) Inventors: Tae-Gyu Kim, Suwon-si (KR); Jin-Tae Jeong, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/521,738

(22) Filed: Sep. 14, 2006

(30) Foreign Application Priority Data
Sep. 15, 2005 (KR) 10-2005-0086373

(51) Int. Cl. G01R 31/28

(52) U.S. Cl. 714/726

(57) ABSTRACT

A scan driver having no shift register and an organic light emitting display device having the same are disclosed. The scan driver includes a latch unit and a NAND gate instead of a shift register, thereby reducing the area occupied by the driver in a display panel. The scan driver uses only a clock signal and a start pulse, thereby reducing the number of driving lines and transistors and reducing power loss.

### CROSS-REFERENCE TO RELATED APPLICATIONS

This application claims priority to and the benefit of Korean Patent Application No. 10-2005-0086373, filed Sep. 15, 2005, the disclosure of which is incorporated herein by reference in its entirety.

### BACKGROUND OF THE INVENTION

1. Field of the Invention

The present invention relates to an organic light emitting display device, and more particularly, to an organic light emitting display device that comprises a scan driver having a latch unit and a NAND gate.

2. Description of the Related Technology

Recently, liquid crystal display devices (LCDs) and organic light emitting display devices (OLEDs) are often used in portable information devices because of their lightweight and thin profile. Organic light emitting display devices are drawing attention as next generation flat panel display devices because they have better luminance and viewing angle compared to LCDs.

Typically, in an active matrix organic light emitting display device (AMOLED), a pixel includes R, G and B sub-pixels, and each of the R, G and B sub-pixels comprises an organic light emitting display diode. Each of the organic light emitting display diodes comprises an organic emission layer, i.e., an R, G or B organic emission layer interposed between an anode and a cathode. An organic layer formed of the R, G or B organic emission layer emits light in response to a voltage applied between the anode and the cathode.

In the active matrix organic light emitting display device, a voltage programming method or a current programming method is used to drive a matrix (N×M) of organic light emitting display diodes.

FIG. 1 illustrates a conventional organic light emitting display device. The organic light emitting display device includes a pixel portion 10, a scan and emission control driver 20, and a data driver 30.

The pixel portion 10 includes a plurality of pixels P11 to Pnm at intersections of a plurality of scan lines S1 to Sn, a plurality of data lines D1 to Dm, and a plurality of emission control lines E1 to En, and displays an image in response to a data signal applied through the plurality of data lines D1 to Dm.

One pixel Pnm includes red, green and blue sub-pixels. The red, green and blue sub-pixels in the pixel portion 10 have the same pixel circuit configurations and emit red, green and blue light corresponding to a signal applied to the respective organic light emitting diodes. The pixel Pnm combines light emitted by the red, green and blue sub-pixels and displays a specific color.

The data driver 30 supplies a signal corresponding to R, G and B data to the data lines D1 to Dm in response to a data control signal supplied from a timing controller (not shown).

The scan and emission control driver 20 sequentially supplies a scan signal and an emission control signal to the scan lines S1 to Sn and the emission control lines E1 to En in response to a start pulse and a clock signal that are data control signals from the timing controller. The scan and emission control driver 20 includes a shift register for generating an emission control signal, and a plurality of logical gates for performing a logical operation on a preceding emission control signal and a current emission control signal to generate a scan signal.

Recently, a method of adjusting luminance by adjusting a duty cycle of an emission control signal has been widely used in an organic light emitting display device. To this end, the organic light emitting display device separately requires a scan driver and an emission control driver. The scan driver having a shift register increases power consumption and cost because it is required to have many transistors and signal lines. In addition, the shift register increases the design area of the scan driver, which inevitably sacrifices the area of a display panel for displaying an image.

### SUMMARY OF CERTAIN INVENTIVE ASPECTS

One aspect of the invention provides a scan driver comprising a plurality of scan signal generating circuits configured to output a plurality of scan signals, the plurality of the scan signal generating circuits comprising a first scan signal generating circuit which comprises: a first latch unit comprising a first input, a second input, and an output, the first input being configured to receive an immediately preceding scan signal, the second input being configured to receive an immediately succeeding scan signal; and a first NAND gate comprising a first input, a second input, and an output, the first input being connected to the output of the first latch unit, the second input being configured to receive a first clock signal, the output being configured to output a first scan signal.

The plurality of scan signal generating circuits may comprise odd-numbered scan signal generating circuits and even-numbered scan signal generating circuit, the odd-numbered scan signal generating circuits being configured to receive one of two clock signals having a phase difference of half a cycle, the even-numbered scan signal generating circuits being configured to receive the other of the two clock signals. The first scan signal generating circuit may be one of the odd or even-numbered circuits.

The plurality of scan signal generating circuits may further comprise a second scan signal generating circuit. The second scan signal generating circuit may comprise: a second latch unit comprising a first input, a second input, and an output, the first input being connected to the output of the first NAND gate, the second input being configured to receive an immediately succeeding scan signal; and a second NAND gate comprising a first input, a second input, and an output, the first input being connected to the output of the second latch unit, the second input being configured to receive a second clock signal, the second clock signal having a phase difference of half a cycle with respect to the first clock signal, the output being connected to the second input of the first latch unit, the output being configured to output a second scan signal.

The first latch unit may comprise: an input unit configured to receive the immediately preceding scan signal and the immediately succeeding scan signal and to selectively output a positive power supply voltage to the output of the first latch unit depending on the scan signals; and a negative voltage transmission unit configured to receive the positive power supply voltage from the input unit and to selectively output a negative power supply voltage to the output of the first latch unit depending on the scan signals.

The input unit may comprise: a first transistor having a source connected to a positive power supply source, a drain connected to the output of the first latch unit, and a gate connected to the first input of the first latch unit; and a second transistor having a source connected to the positive power supply source, a drain connected to the negative voltage transmission unit, and a gate connected to the second input of the first latch unit. The negative voltage transmission unit may comprise: a third transistor having a source connected to a negative power supply source, a drain connected to the drain of the second transistor, and a gate connected to the drain of the first transistor; and a fourth transistor having a source connected to the negative power supply source, a drain connected to the drain of the first transistor, and a gate connected to the drain of the second transistor. The first and second transistors may have a different conductivity type from that of the third and fourth transistors.

The NAND gate may comprise: a positive voltage transmission unit configured to selectively output a scan signal having a positive power supply voltage level depending on an output signal of the first latch unit and the first clock signal; and a negative voltage transmission unit configured to selectively output a scan signal having a negative power supply voltage level depending on the output signal of the first latch unit and the first clock signal.

The positive voltage transmission unit may comprise two transistors connected in parallel between a positive power supply voltage source and the output of the first NAND gate, one of the transistors having a gate connected to the output of the first latch unit, the other of the transistors having a gate configured to receive the first clock signal. The negative voltage transmission unit may comprise two transistors connected in series between a negative power supply voltage source and the output of the first NAND gate, one of the transistors having a gate connected to the output of the first latch unit, the other of the transistors having a gate configured to receive the first clock signal. The transistors of the positive voltage transmission unit may have a conductivity type different from that of the transistors of the negative voltage transmission unit. The first scan signal generating circuit may further comprise a buffer unit having an input connected to the output of the first NAND gate and an output configured to supply the first scan signal.

Another aspect of the invention provides a display device comprising the scan driver described above. The display device may comprise an organic light emitting display device. The display device may further comprise: an array of pixels; and an emission control driver configured to supply an emission control signal to the pixels, wherein the scan driver is configured to supply the plurality of scan signals to the pixels.

Another aspect of the invention provides a scan driver comprising a plurality of scan signal generating circuits configured to output a plurality of scan signals, the plurality of the scan signal generating circuits comprising: a first scan signal generating circuit configured to generate a first scan signal; a second scan signal generating circuit configured to generate a second scan signal; and a third scan signal generating circuit configured to generate a third scan signal. The second scan signal generating circuit comprises: means for receiving the first scan signal and the third scan signal and generating a second output signal such that the second output signal has a high-level from a falling edge of the first scan signal to a falling edge of the third scan signal; and means for logically combining the second output signal and one of two clock signals having a phase difference of half a cycle, thereby generating the second scan signal.

The first scan signal, the second scan signal, and the third scan signal may be sequentially output. The first scan signal generating circuit may comprise: means for receiving a start pulse signal and the second scan signal and generating a first output signal such that the first output signal has a high-level from a falling edge of the start pulse signal to a falling edge of the second scan signal; and means for conducting a NAND operation on the first output signal and the other of the two clock signals, thereby generating the first scan signal.

The plurality of the scan signal generating circuits may comprise a fourth scan signal generating circuit configured to generate a fourth scan signal, and the third scan signal generating circuit may comprise: means for receiving the second scan signal and the fourth scan signal and generating a third output signal such that the third output signal has a high-level from a falling edge of the second scan signal to a falling edge of the fourth scan signal; and means for conducting a NAND operation on the third output signal and the other of the two clock signals, thereby generating the third scan signal.

Another aspect of the invention provides a display device comprising the scan driver described above.

Yet another aspect of the invention provides a method of generating a plurality of scan signals for a display device. The method comprises: generating a first scan signal; generating a second scan signal; and generating a third scan signal. Generating the second scan signal comprises: receiving the first scan signal and the third scan signal; generating a second output signal based on the first scan signal and the third scan signal such that the second output signal has a high-level from a falling edge of the first scan signal to a falling edge of the third scan signal; conducting a NAND operation on the second output signal and one of two clock signals having a phase difference of half a cycle, thereby generating the second scan signal.

Generating the third scan signal may comprise: receiving the second scan signal and an immediately succeeding scan signal; generating a third output signal based on the second scan signal and the immediately succeeding scan signal such that the third output signal has a high-level from a falling edge of the second scan signal to a falling edge of the immediately succeeding scan signal; conducting a NAND operation on the third output signal and the other of the two clock signals, thereby generating the third scan signal.

Another aspect of the invention provides an organic light emitting display device that separately drives a scan driver and an emission control driver, capable of optimizing power consumption, saving cost, and obtaining the area of a display panel by designing a simplified scan driver without using a shift register.

Another aspect of the invention provides a scan driver including a plurality of scan signal generating circuits that output each scan signal, each of the scan signal generating circuits having: a latch unit for receiving a first scan signal and a third scan signal and generating a high-level output signal to a falling edge of the third scan signal in synchronization with a falling edge of the first scan signal; and a NAND gate for receiving one of two clock signals having a phase difference of half a cycle and the output signal of the latch unit to perform a logical operation on the two signals and outputting a second scan signal, wherein the first scan signal, the second scan signal, and the third scan signal are sequentially output.

Another aspect of the invention provides an organic light emitting display device which includes: a pixel portion for displaying an image; an emission control driver for supplying an emission control signal to the pixel portion; and a scan driver having a plurality of scan signal generating circuits for supplying each scan signal to the pixel portion, wherein each of the scan signal generating circuits comprises: a latch unit for receiving a first scan signal and a third scan signal and generating a high-level output signal to a falling edge of the third second scan signal in synchronization with a falling edge of the first scan signal; and a NAND gate for receiving one of two clock signals having a phase difference of half a cycle and the output signal of the latch unit to perform a logical operation on the two signals and outputting the second scan signal, wherein the first scan signal, the second scan signal, and the third scan signal are sequentially output.

### BRIEF DESCRIPTION OF THE DRAWINGS

The above and other features of the instant disclosure will be described in reference to certain exemplary embodiments thereof with reference to the attached drawings in which:

FIG. 1 illustrates a conventional organic light emitting display device;

FIG. 2 illustrates an organic light emitting display device according to an embodiment;

FIG. 3 illustrates a scan driver according to an embodiment;

FIG. 4 is a circuit diagram of a latch unit of a scan driver according to an embodiment;

FIG. 5 is a circuit diagram of a NAND gate and a buffer unit of a scan driver according to an embodiment;

FIG. 6 is a timing diagram illustrating the operation of a scan driver according to an embodiment;

FIG. 7 illustrates an emission control driver according to an embodiment;

FIG. 8 is a circuit diagram of an emission control driver according to an embodiment; and

FIG. 9 is a timing diagram illustrating the operation of an emission control driver according to an embodiment.

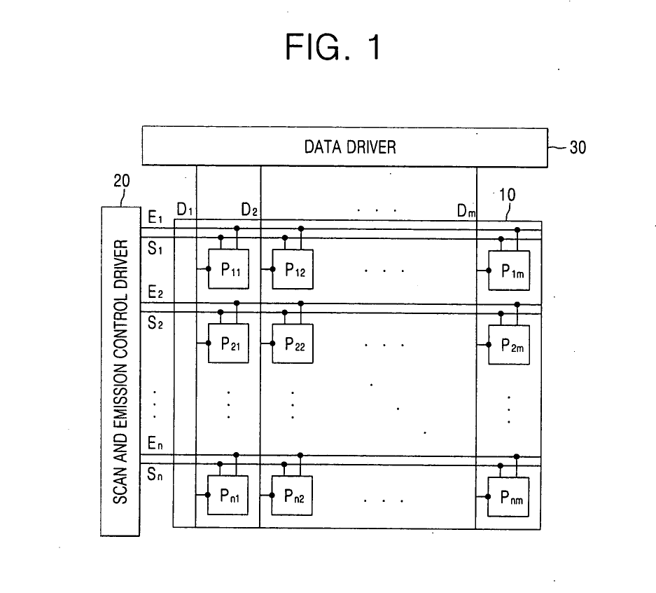

### DETAILED DESCRIPTION OF CERTAIN INVENTIVE EMBODIMENTS

The instant disclosure will now be described more fully hereinafter with reference to the accompanying drawings, in which exemplary embodiments of the invention are shown.

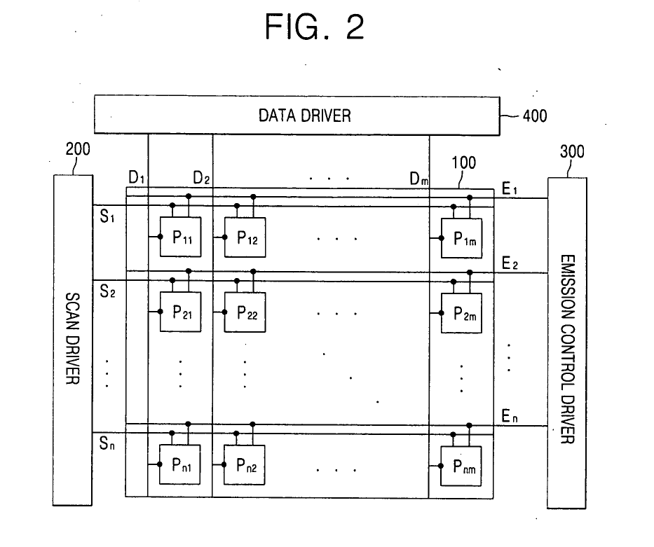

FIG. 2 illustrates one embodiment of an organic light emitting display device. Referring to FIG. 2, the organic light emitting display device includes a pixel portion 100, a scan driver 200, an emission control driver 300, and a data driver 400.

The pixel portion 100 includes a plurality of pixels P11 to Pnm formed in regions defined by a plurality of scan lines S1 to Sn, a plurality of emission control lines E1 to En, and a plurality of data lines D1 to Dm. Each pixel Pnm includes red, green and blue sub-pixels, which are connected to respective data lines receiving data signals from the data driver 400.

The red, green and blue sub-pixels of each pixel Pnm have the same pixel circuit configuration. The red, green and blue sub-pixels emit red, green and blue light corresponding to a current applied to the organic light emitting diode (OLED) to display a specific color.

The scan driver 200 sequentially supplies a predetermined scan signal to the plurality of scan lines S1 to Sn in synchronization with a start pulse and a clock signal that are timing control signals supplied from a timing controller (not shown).

The emission control driver 300 includes a shift register. The emission control driver 300 outputs an emission control signal in synchronization with the start pulse and the clock signal that are timing control signals supplied from the timing controller. A duty cycle of the clock signal may be controlled by the timing controller every frame so that respective frames maintain the same luminance.

The data driver 400 is connected to the plurality of data lines D1 to Dm and applies a data signal to the data lines to display a pixel selected by the scan signal supplied from the scan driver 200. That is, a driving current corresponding to the data signal is applied to the pixel and transmitted to the organic light emitting diode (OLED) through the electrical connection of the pixel circuit formed in the pixel. As a result, the organic light emitting diode displays an image.

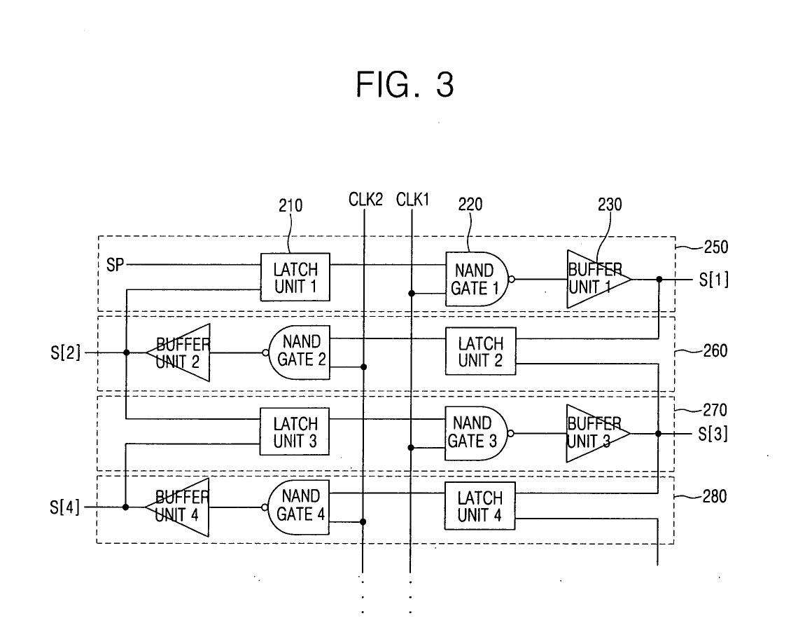

FIG. 3 illustrates the configuration of a scan driver according to an embodiment. Referring to FIG. 3, the scan driver includes a plurality of scan signal generating circuits 250, 260, 270, and 280.

The first scan signal generating circuit 250 includes a first latch unit 210, a first NAND gate 220, and a first buffer unit 230. The first latch unit 210 receives a start pulse SP from a timing controller (not shown) and a second scan signal S2 from a second scan signal generating circuit, and outputs to the first NAND gate 220 an output signal maintaining a high level from a falling edge of the start pulse SP to a falling edge of the second scan signal S2.

The first NAND gate 220 performs a logical operation on the output signal of the first latch unit 210 and a first clock signal CLK1, and generates an output signal. The first NAND gate 220 generates a low-level output signal only in a cycle during which both of input signals are maintained at a high level and a high-level output signal in other cycles.

The first buffer unit 230 generates a first scan signal S1 of which the level is high or low according to the output signal of the first NAND gate 220, and supplies the first scan signal S1 to the pixel portion 100 and the second latch unit 210 of the second scan signal generating circuit 260.

The second scan signal generating circuit 260 includes a second latch unit 210, a second NAND gate 220, and a second buffer unit 230. The second latch unit 210 receives the first scan signal S1 from the first scan signal generating circuit 250 and a third scan signal S3 from the third scan signal generating circuit, and outputs to the second NAND gate 220 an output signal that is maintained at a high level from a falling edge of the first scan signal S1 to a falling edge of the third scan signal S3.

The second NAND gate 220 receives the output signal of the second latch unit 210 and a second clock signal CLK2 and performs a logical operation on the received signals to generate an output signal. The second buffer unit 230 generates a second scan signal S2 whose level is up or down according to the output signal of the second NAND gate 220, and supplies the second scan signal S2 to the pixel portion 100 and the first and third latch units 210 of the first and third scan signal generating circuits 250 and 270.

Successive scan signal generating circuits receive preceding and succeeding scan signals Sn−1 and Sn+1 via its latch unit 210, and generates an output signal as described above, and its buffer unit 230 supplies a current scan signal Sn to the pixel portion 100 and the preceding and succeeding latch units 210.

In the illustrated embodiment, odd-numbered scan signal generating circuits receive the first clock signal CLK1 at the NAND gates whereas even-numbered scan signal generating circuits receive the second clock signal CLK2 at the NAND gates. The second clock signal CLK2 is a signal shifted by half a cycle relative to the first clock signal CLK1. A first inverted clock signal CLK1 may be used, if necessary.

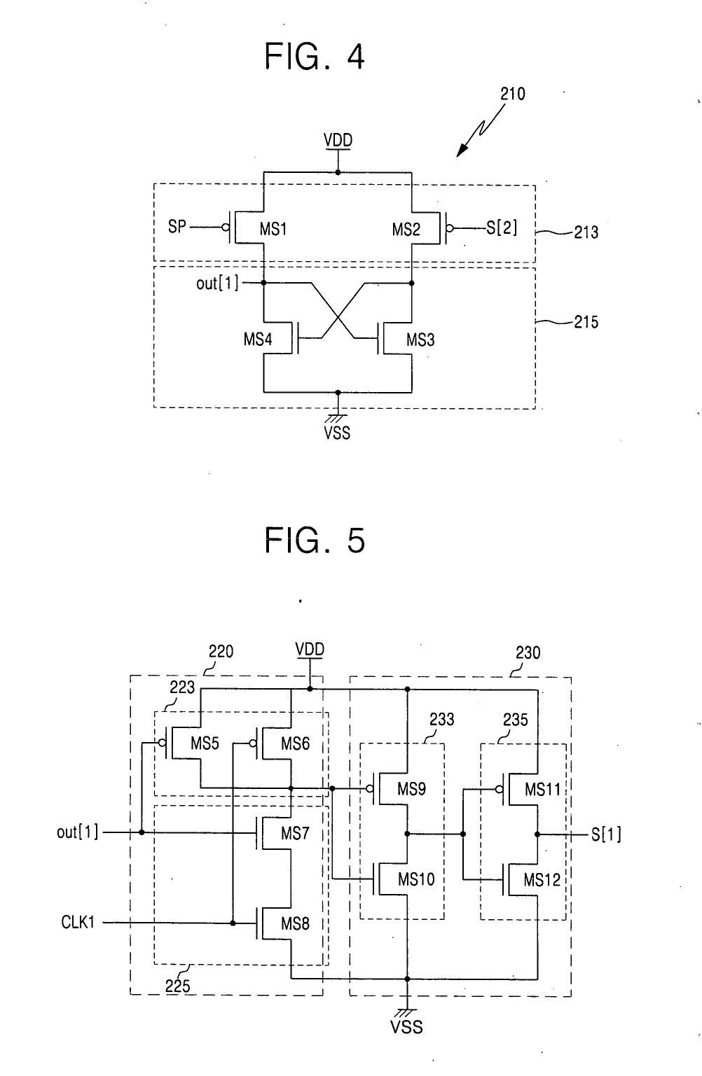

Hereinafter, the configurations of the latch unit, the NAND gate, and the buffer unit will be described in detail with reference to FIGS. 4 and 5.

FIG. 4 is a circuit diagram of a latch unit of a scan driver according to an embodiment. Referring to FIG. 4, the latch unit includes an input unit 213 and a negative voltage supply unit 215. The first latch unit 210 of the first scan signal generating circuit 250 will now be described as an example.

First, the input unit 213 includes a first transistor MS1 and a second transistor MS2 that are connected between a positive power supply voltage VDD and a negative voltage transmission unit 215.

The transistor MS1 has a source connected to the positive power supply voltage VDD, and a drain connected to an output terminal out1 and a gate of a third transistor MS3. The transistor MS1 is turned on/off in response to a start pulse SP supplied from a timing controller (not shown).

The second transistor MS2 has a source connected to the positive power supply voltage VDD, and a drain connected to a drain of the third transistor MS3 and a gate of a fourth transistor MS4. The second transistor MS2 is turned on/off in response to a second scan signal S2 supplied from the second scan signal generating circuit 260.

The negative voltage transmission unit 215 includes the third transistor MS3 and the fourth transistor MS4 that are connected between a negative power supply voltage VSS and the input unit 213.

The third transistor MS3 has a source connected to a negative power supply voltage VSS, and a drain connected to the drain of the second transistor MS2 and the gate of the fourth transistor MS4. The third transistor MS3 is turned on/off in response to the output signal of the first transistor MS1, and supplies the negative power supply voltage VSS to the gate of the fourth transistor MS4.

The fourth transistor MS4 has a source connected to the negative power supply voltage VSS and a drain connected to the output terminal out1. The fourth transistor MS4 is turned on/off in response to output signals of the second and third transistors MS2 and MS3.

The operation of the first latch unit 210 will now be described. When a low-level start pulse SP is applied to the first transistor MS1 and a high-level second scan signal S2 is applied to the second transistor MS2, the first transistor MS1 is turned on. Accordingly, a high-level output signal having the positive power supply voltage VDD level is generated at the output terminal out1.

When a high-level start pulse SP is applied to the first transistor MS1 and a high-level second scan signal S2 is applied to the second transistor MS2, both the first and second transistors MS1 and MS2 are turned off. At this time, the third transistor MS3 is turned on by the preceding output signal having a high level to supply the negative power supply voltage VSS to the fourth transistor MS4. Accordingly, since the fourth transistor MS4 is turned off, the preceding output signal having the high level is kept unchanged at the output terminal out1.

When a high-level start pulse SP is applied to the first transistor MS1 and a low-level second scan signal S2 is applied to the second transistor MS2, the second transistor MS2 is turned on to supply the positive power supply voltage VDD to the fourth transistor MS4. Accordingly, the fourth transistor MS4 is turned on and a low-level output signal having the negative power supply voltage VSS level is output at the output terminal out1.

As a result, the first latch unit 210 outputs to the first NAND gate 220 an output signal that is kept at the high level from a falling edge of the start pulse SP to a falling edge of the second scan signal S2.

FIG. 5 is a circuit diagram of a NAND gate and a buffer unit of a scan driver according to an embodiment. The first NAND gate and the first buffer unit of the scan driver will now be described.

Referring to FIG. 5, the first NAND gate 220 includes a positive voltage transmission unit 223 for receiving an output signal of the first latch unit 210 and the first clock signal CLK1 to supply the positive power supply voltage VDD to the output terminal, and a negative voltage transmission unit 225 for receiving the output signal of the first latch unit 210 and the first clock signal CLK1 to supply the negative power supply voltage VSS to the output terminal.

The positive voltage transmission unit 223 includes two switching transistors MS5 and MS6 connected in parallel between the positive power supply voltage VDD and the output terminal.

The switching transistor MS5 has a source connected to the positive power supply voltage VDD and a drain connected to the output terminal. The switching transistor MS5 is turned on/off in response to the output signal of the first latch unit 210 to transmit the positive power supply voltage VDD to the output terminal.

The second switching transistor MS6 has a source connected to the positive power supply voltage VDD and a drain connected to the output terminal. The second switching transistor MS6 is turned on/off in response to the first clock signal CLK1 to transmit the positive power supply voltage VDD to the output terminal.

The negative voltage transmission unit 225 includes two switching transistors MS7 and MS8 connected in series between the negative power supply voltage VSS and the output terminal.

The third switching transistor MS7 has a source connected to a drain of the fourth switching transistor MS8 and a drain connected to the output terminal. The third switching transistor MS7 is turned on/off in response to the output signal of the first latch unit 210 to transmit an output signal of the fourth switching transistor MS8 to the output terminal.

The fourth switching transistor MS8 has a source connected to the negative power supply voltage VSS and a drain connected to the third switching transistor MS7. The fourth switching transistor MS8 is turned on/off in response to the first clock signal CLK1 to transmit the negative power supply voltage VSS to the third switching transistor MS7.

The first NAND gate 220 outputs a low-level output signal only when the output signal of the first latch unit 210 and the first clock signal CLK1 are at a high level, and otherwise, outputs a high-level output signal. The positive voltage transmission unit 223 and the negative voltage transmission unit 225 of the first NAND gate 220 include transistors having opposite conductivity types. In the illustrated embodiment, the transistors MS5 and MS6 of the positive voltage transmission unit 223 are P-type MOSFETs, and the transistors MS7 and MS8 of the negative voltage transmission unit 225 are N-type MOSFETs depending on a signal waveform. In other embodiments, the conductivity types of the MOSFETs may be different from those of the illustrated MOSFETs.

This scan signal generating circuit 250 further includes a first buffer unit 230 for increasing or decreasing the output signal of the first NAND gate 220 to a voltage level to turn the transistors of the pixel portion 100 on/off. The buffer unit 230 includes two inverters 233 and 235.

The first inverter 233 includes two transistors MS9 and MS10 that are selectively turned on/off in response to the simultaneously supplied output signal of the first NAND gate 220 to transmit the positive power supply voltage VDD or the negative power supply voltage VSS. The first inverting transistor MS9 has a source connected to the positive power supply voltage VDD and a drain connected to the output terminal. The first inverting transistor MS9 is turned on/off in response to the output signal of the first NAND gate 220 to output the positive power supply voltage VDD.

The second inverting transistor MS10 has a source connected to the negative power supply voltage VSS and a drain connected to the output terminal. The second inverting transistor MS10 is turned on/off in response to the output signal of the first NAND gate 220 to output the negative power supply voltage VSS.

The first and second inverting transistors MS9 and MS10 have opposite conductivity types. In the illustrated embodiment, the first inverting transistor MS9 is a P-type MOSFET and the second inverting transistor MS10 is an N-type MOSFET depending on a signal waveform. The first and second inverting transistors MS9 and MS10 are selectively turned on in response to the output signal of the first NAND gate 220. Accordingly, when the output signal of the first NAND gate 220 is at a high level, the second inverting transistor MS10 is turned on and the negative power supply voltage VSS is output. On the other hands when the output signal of the first NAND gate 220 is at a low level, the first inverting transistor MS9 is turned on and the positive power supply voltage VDD is output.

The second inverter 235 includes two transistors MS11 and MS12 that receive the output signal of the first inverter 233 to output a first inverted scan signal S[1]. The third inverting transistor MS11 has a source connected to the positive power supply voltage VDD and a drain connected to the output terminal. The third inverting transistor MS11 is turned on/off in response to the output signal of the first inverter 233 to output a high-level first scan signal S[1] having the positive power supply voltage VDD level.

The fourth inverting transistor MS12 has a source connected to the negative power supply voltage VSS and a drain connected to the output terminal. The fourth inverting transistor MS12 is turned on/off in response to the output signal of the first inverter 233 to output a low-level first scan signal S1 having the negative power supply voltage VSS level.

The third and fourth inverting transistors MS 11 and MS12 have opposite conductivity types. In the illustrated embodiment, the third inverting transistor MS11 is a P-type MOSFET and the fourth inverting transistor MS12 is an N-type MOSFET depending on a signal waveform. The third and fourth inverting transistors MS11 and MS12 are selectively turned on in response to the output signal of the first inverter 233. Accordingly, when the output signal of the first inverter 233 is at a high level, the fourth inverting transistor MS12 is turned on and the first scan signal S1 having the negative power supply voltage VSS level is output. When the output signal of the first inverter 233 is at a low level, the third inverting transistor MS11 is turned on and the first scan signal S [1] having the positive power supply voltage VDD level is output.

In the first buffer unit 230, the output signal of the first NAND gate 220 is inverted by the first inverter 233 and again inverted by the second inverter 235, such that the first scan signal S1 having the same waveform as the output signal of the first NAND gate 220 is output. The first scan signal S[1] has the same duty cycle as the output signal of the first NAND gate 220 but has a larger amplitude, thereby performing on/off operation of the transistors of the pixel portion 100.

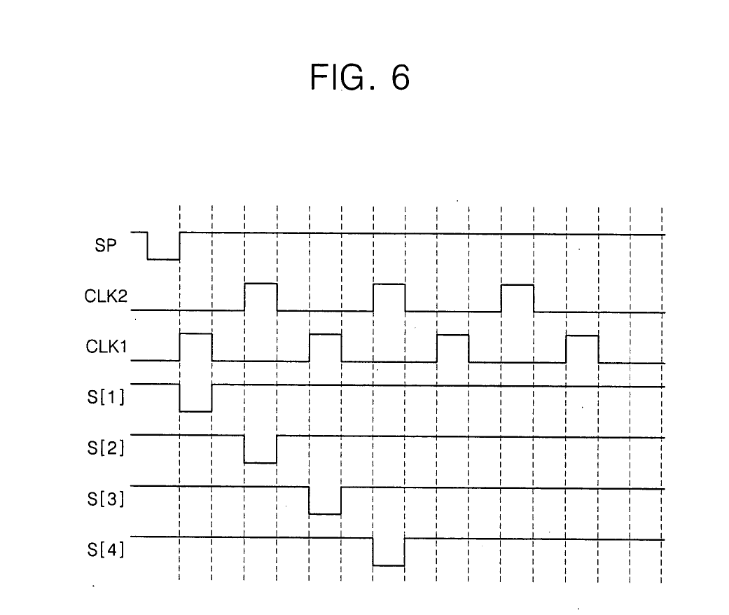

FIG. 6 is a timing diagram illustrating the operation of a scan driver according to an embodiment. Referring to FIG. 6, in each scan signal generating circuit 250, 260, 270, or 280, the latch unit 210 of the scan signal generating circuit 250, 260, 270, or 280 receives a preceding scan signal Sn−1 and a succeeding scan signal Sn+1.

When a start pulse SP and a second scan signal S2 are applied to the first latch unit 210 of the first scan signal generating circuit 250, the first latch unit 210 supplies to the first NAND gate 220 an output signal that is kept at a high level from a falling edge of the start pulse SP to a falling edge of the second scan signal S[2].

The first NAND gate 220 receives the output signal of the first latch unit 210 and the first clock signal CLK1. The first NAND gate 220 performs a logical operation on the output signal of the first latch unit 210 and the first clock signal CLK1, and supplies a low-level output signal to the first buffer unit 230 during a cycle in which both the first clock signal CLK1 and the output signal of the first latch unit 210 are at a high level.

The first buffer unit 230 receives the output signal of the first NAND gate 220, and outputs the first scan signal S[1] having the negative power supply voltage VSS level sufficient to turn on the transistors of the pixel portion 100 when the output signal is kept at the low level.

Next, when the first scan signal S[1] and the third scan signal S[3] are applied to the second latch unit 210 of the second scan signal generating circuit 260, the second latch unit 210 supplies to the second NAND gate 220 an output signal that is kept at a high level from a falling edge of the first scan signal S[1] to a falling edge of the third scan signal S[3].

The second NAND gate 220 receives the output signal of the second latch unit 210 and the second clock signal CLK2. The second clock signal CLK2 is shifted by half a cycle relative to the first clock signal CLK1, and is input to the second NAND gate 220. The second NAND gate 220 performs a logical operation on the output signal of the second latch unit 210 and the second clock signal CLK2, and supplies a low-level output signal to the second buffer unit 230 during a cycle in which both the second clock signal CLK2 and the output signal of the second latch unit 210 are at a high level.

The second buffer unit 230 receives the output signal of the second NAND gate 220 to output the second scan signal S[2] having the negative power supply voltage VSS level sufficient to turn on the transistors of the pixel portion 100 when the output signal is kept at a low level.

After the above-described operation is repeated, when an n-th scan signal generating circuit finally outputs an n-th scan signal Sn, a one-frame image is displayed on the pixel portion 100.

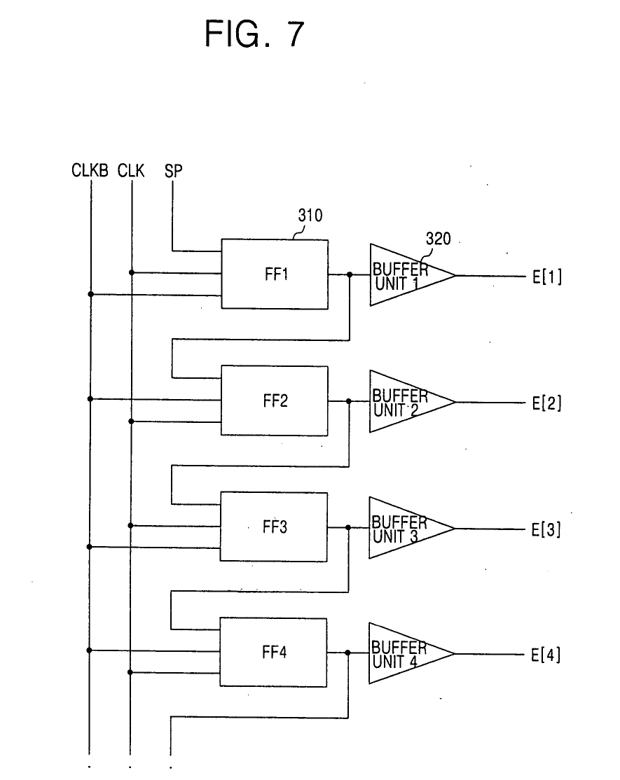

FIG. 7 illustrates the configuration of an emission control driver according to an embodiment. Referring to FIG. 7, the emission control driver 300 includes a plurality of flip flops 310 FF1, FF2, FF3, . . . , and a plurality of buffer units 320.

The first flip flop FF1 receives a start pulse SP, a clock signal CLK, and an inverted clock signal CLKB, and generates a first output signal maintaining a high-level start pulse SP to a rising edge of the clock signal CLK.

The second flip flop FF2 receives the first output signal of the first flip flop FF1 as an input signal and is synchronized with the clock signal CLK and the inverted clock signal CLKB. The second flip flop FF2 receives the clock signal CLK and the inverted clock signal CLKB at inputs different from those of the first flip flop FF1 such that the clock signals CLK, CLKB are inverse from those supplied to the first flip flop FF1. The second flip flop FF2 samples the first output signal of the first flip flop FF at a rising edge of the inverted clock signal CLKB that is shifted by half a clock cycle. The second flip flop FF2 generates a second output signal that is kept during one clock cycle. Accordingly, the second output signal of the second flip flop FF2 is shifted by half a clock cycle relative to the first output signal of the first flip flop FF1.

Successive flip flops FF3, FF4, . . . receive an output signal of the preceding flip flop, sample the output signal on a rising edge of the clock signal CLK or the inverted clock signal CLKB, and sequentially output signals shifted by half a clock cycle.

Each flip flop 310 is connected to the buffer unit 320 for receiving the output signal of the flip flop to increase or decrease the output signal to a sufficient voltage level to turn on/off the transistors of the pixel portion 100. Each buffer unit 320 receives the output signal from a flip flop 310 connected thereto, and outputs a high-level emission control signal En having the positive power supply voltage level when the output signal is at a high level and a low-level emission control signal En having the negative power supply voltage level when the output signal is at a low level.

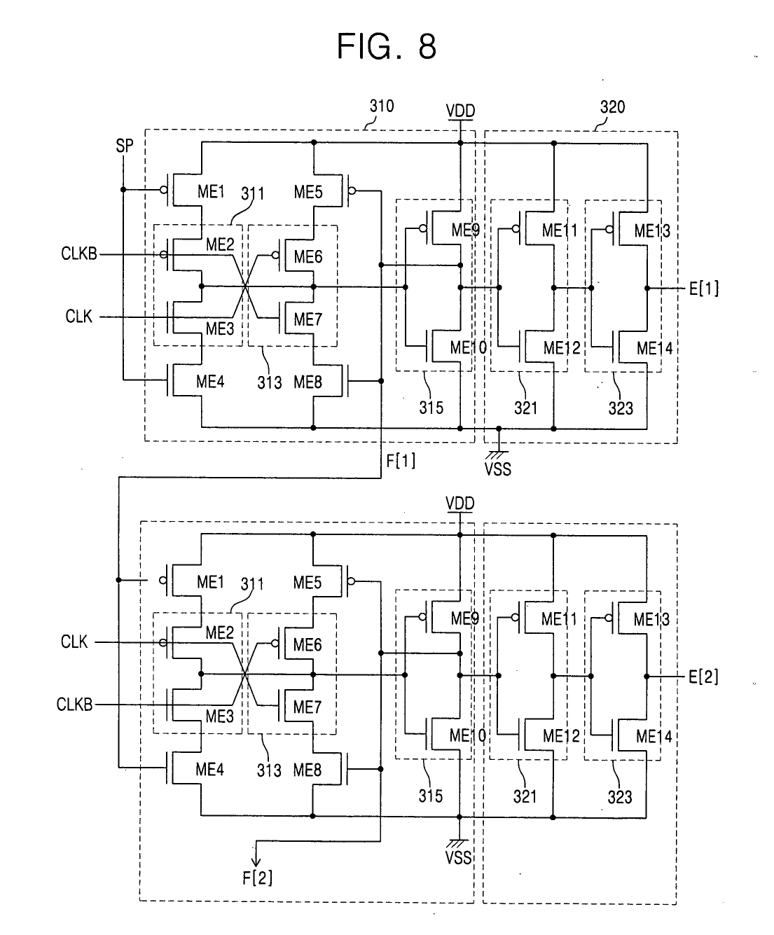

The configuration of the flip flop 310 and the buffer unit 320 will now be described in detail. FIG. 8 is a circuit diagram of an emission control driver according to one embodiment.

Referring to FIG. 8, the emission control driver 300 includes a plurality of emission control driving circuits for receiving a preceding output signal En-1 to generate an emission control signal En. For convenience of illustration, only first and second emission control driving circuits will be described with reference to FIG. 8.

The first emission control driving circuit includes a first flip flop 310 FF1 for receiving a clock signal CLK, an inverted clock signal CLKB, and a start pulse SP to generate a first flip flop output signal F1. The first emission control driving circuit also includes a buffer unit 320 for receiving the first flip flop output signal F1 to adjust the voltage level of the signal and generate a first emission control signal E 1.

The first flip flop 310 includes four voltage transmission transistors ME1, ME4, ME5, and ME8 and three switching units 311, 313 and 315.

The first voltage transmission transistor ME1 has a source connected to a positive power supply voltage VDD and a drain connected to the first switching unit 311. The voltage transmission transistor ME1 is turned on/off in response to the start pulse SP to transmit the positive power supply voltage VDD to the first switching unit 311.

The second voltage transmission transistor ME4 has a source connected to a negative power supply voltage VSS and a drain connected to the first switching unit 311. The second voltage transmission transistor ME4 is turned on/off in response to the start pulse SP to transmit the negative power supply voltage VSS to the first switching unit 311. The first and second voltage transmission transistors ME1 and ME4 have different conductivity types. In the illustrated embodiment, the first voltage transmission transistor ME1 is a P-type MOSFET and the second voltage transmission transistor ME4 is an N-type MOSFET depending on a signal waveform.

The third voltage transmission transistor ME5 has a source connected to the positive power supply voltage VDD and a drain connected to the second switching unit 313. The third voltage transmission transistor ME5 is turned on/off in response to the first flip flop output signal F1 to transmit the positive power supply voltage VDD to the second switching unit 313.

The fourth voltage transmission transistor ME8 has a source connected to the negative power supply voltage VSS and a drain connected to the second switching unit 313. The fourth voltage transmission transistor ME8 is turned on/off in response to the first flip flop output signal F1 to transmit the negative power supply voltage VSS to the second switching unit 313. The third and fourth voltage transmission transistors ME5 and ME8 have different conductivity types. In the illustrated embodiment, the third voltage transmission transistor ME5 is a P-type MOSFET, and the fourth voltage transmission transistor ME8 is an N-type MOSFET depending on a signal waveform.

The first switching unit 311 includes two transistors ME2 and ME3 having different conductivity types from each other.

The first transistor ME2 has a source connected to the drain of the first voltage transmission transistor ME1 and a drain connected to an output terminal. The first transistor ME2 is turned on/off in response to the inverted clock signal CLKB to output the positive power supply voltage VDD to the output terminal.

The second transistor ME3 has a source connected to the drain of the second voltage transmission transistor ME4 and a drain connected to the output terminal. The second transistor ME3 is turned on/off in response to the clock signal CLK to output the negative power supply voltage VSS to the output terminal.

The second switching unit 313 includes two transistors ME6 and ME7 having different conductivity types from each other.

The third transistor ME6 has a source connected to the drain of the third voltage transmission transistor ME5 and a drain connected to the output terminal. The third transistor ME6 is turned on/off in response to the clock signal CLK to output the positive power supply voltage VDQ to the output terminal.

The fourth transistor ME7 has a source connected to the drain of the fourth voltage transmission transistor ME8 and a drain connected to the output terminal. The fourth transistor ME7 is turned on/off in response to the inverted clock signal CLKB to output the negative power supply voltage VSS to the output terminal. The outputs of the first and second switching units 311 and 313 are connected to an input terminal of the third switching unit 315.

The third switching unit 315 includes two transistors ME9 and ME10 having different conductivity types from each other.

The fifth transistor ME9 has a source connected to the positive power supply voltage VDD and a drain connected to the output terminal of the first flip flop FF1. The fifth transistor ME9 is turned on/off in response to output signals at the output terminals of the first and second switching units 311 and 313 to output the first flip flop output signal F1.

The sixth transistor ME10 has a source connected to the negative power supply voltage VSS and a drain connected to the output terminal of the first flip flop FF1. The sixth transistor ME10 is turned on/off in response to the output signals at the output terminals of the first and second switching units 311 and 313 to output the first flip flop output signal F1.

In the illustrated first, second and third switching units 311, 313 and 315, the transistors ME2, ME6 and ME9 connected to the positive power supply voltage VDD are P-type MOSFETs whereas the transistors ME3, ME7 and ME10 connected to the negative power supply voltage VSS are N-type MOSFETs depending on a signal waveform.

The buffer unit 320 includes two inverters 321 and 323. The first inverter 321 receives the first flip flop output signal F1 to supply a power supply voltage having an inverted level to the second inverter 323. The second inverter 323 receives the output signal of the first inverter 321 to supply the first emission control signal E1 having an inverted level to the pixel portion 100.

Accordingly, the first emission control signal E1 having the same waveform as the first flip flop output signal F1 is supplied to the pixel portion 100. The amplitude of the signal E1 is at the positive power supply voltage VDD or the negative power supply voltage VSS level sufficient to turn on or off the transistor of the pixel portion.

The second emission control driving circuit has the same configuration as the first emission control driving circuit except that the clock signal CLK and the inverted clock signal CLKB are supplied to the first and second switching units 311 and 313 inversely from those supplied to the first emission control driving circuit. In the illustrated embodiment, the clock signal CLK is supplied to the first and fourth transistors ME2 and ME7, and the inverted clock signal CLKB is supplied to the second and third transistors ME3 and ME6. In addition, in the second emission control driving circuit, the output signal F1 of the first flip flop FF1 is supplied to the transistors ME1 and ME4. Thus, the first and second flip flops FF1 and FF2 continuously output the output signals F1 and F2 that are shifted by half a clock cycle.

In successive emission control driving circuits FF3, FF4, . . . , odd-numbered emission control driving circuits receive the clock signal CLK and the inverted clock signal CLKB, like the first emission control driving circuit, and even-numbered emission control driving circuits receive the inverted clock signal CLKB and the clock signal CLK, like the second emission control driving circuit.

Operations of the first and second emission control driving circuits will now be described. First, a high-level clock signal CLK and a low-level inverted clock signal CLKB are supplied to the first flip flop FF1 of the first emission control driving circuit. When a high-level start pulse SP is supplied to the first flip flop 310 FF1. Then, the second voltage supply transistor ME4 and the second transistor ME3 of the first switching unit 311 are turned on and the negative power supply voltage VSS is supplied to an input terminal of the third switching unit 315.

The negative power supply voltage VSS is supplied to the third switching unit 315 to turn the fifth transistor ME9 on, and the first flip flop output signal F1 having the positive power supply voltage VDD level is output to the buffer unit 320. The buffer unit 320 receives the first flip flop output signal F1 to output a high-level first emission control signal E1 having a corresponding positive power supply voltage VDD level.

Next, when the clock signal CLK is changed to a low level and the inverted clock signal CLKB is changed to a high level, the two transistors ME2 and ME3 of the first switching unit 311 are turned off and the two transistors ME6 and ME7 of the second switching unit 313 are turned on.

Further, the fourth voltage transmission transistor ME8 is turned on by the positive power supply voltage VDD that is the preceding state of the first flip flop output signal F1. Accordingly, the negative power supply voltage VSS is transmitted to the input terminal of the third switching unit 315 via the fourth voltage transmission transistor ME8 and the fourth transistor ME7, and the first flip flop output signal F1 having the positive power supply voltage VDD level is output.

Finally, when the clock signal CLK is changed to a high level and the inverted clock signal CLKB is changed to a low level, the two transistors ME2 and ME3 of the first switching unit 311 are turned on. At this time, a low-level start pulse SP is supplied to the first flip flop 310 FF1 and the positive power supply voltage VDD is supplied to the input terminal of the third switching unit 315. Accordingly, the sixth transistor ME10 of the third switching unit 315 is turned on and the first flip flop output signal F1 having the negative power supply voltage VSS level is output to the buffer unit 320.

Accordingly, the first emission control signal E1 output from the buffer unit 320 is kept at a high level from a rising edge of the start pulse SP to a rising edge of the clock signal CLK, and changed to a low level at the rising edge of the clock signal CLK.

The second emission control driving circuit receives the first flip flop output signal F1 from the first emission control driving circuit, and receives the clock signal CLK and the inverted clock signal CLKB from a timing controller (not shown).

First, a low-level clock signal CLK and a high-level inverted clock signal CLKB are supplied to the second flip flop FF2. When the a high-level first flip flop output signal F1 is supplied at this time, the second voltage supply transistor ME4 and the second transistor ME3 of the first switching unit 311 are turned on and the negative power supply voltage VSS is supplied to the input terminal of the third switching unit 315. The negative power supply voltage VSS is supplied to the third switching unit 315 and the fifth transistor ME9 is turned on to output the second flip flop output signal F2 having the positive power supply voltage VDD level to the buffer unit 320. The buffer unit 320 receives the second flip flop output signal F2 and outputs a high-level second emission control signal E2 having a corresponding positive power supply voltage VDD level.

Next, when the clock signal CLK is changed to a high level and the inverted clock signal CLKB is changed to a low level, the two transistors ME2 and ME3 of the first switching unit 311 are turned off, and the two transistors ME6 and ME7 of the second switching unit 313 is turned on. At this time, the fourth voltage transmission transistor ME8 is turned on by the positive power supply voltage VDD that is the preceding state of the second flip flop output signal F2. Accordingly, the negative power supply voltage VSS is transmitted to the input terminal of the third switching unit 315 via the fourth voltage transmission transistor ME8 and the fourth transistor ME7, and the second flip flop output signal F2 having the positive power supply voltage VDD level is output.

Finally, when the clock signal CLK is changed to a low level again and the inverted clock signal CLKB is changed to a high level, the two transistors ME2 and ME3 of the first switching unit 311 are turned on. At this time, the first flip flop output signal F1 having a low level is supplied to the second flip flop 310 FF2. Then, the positive power supply voltage VDD is supplied to the input terminal of the third switching unit 315. Accordingly, the sixth transistor ME10 of the third switching unit 315 is turned on and the second flip flop output signal F2 having the negative power supply voltage VSS level is output to the buffer unit 320.

As a result, the second emission control signal E2 output from the buffer unit 320 is sampled at a falling edge of the clock signal CLK (a rising edge of the inverted clock signal) in response to the first flip flop output signal F1, and kept at a high level during one clock cycle.

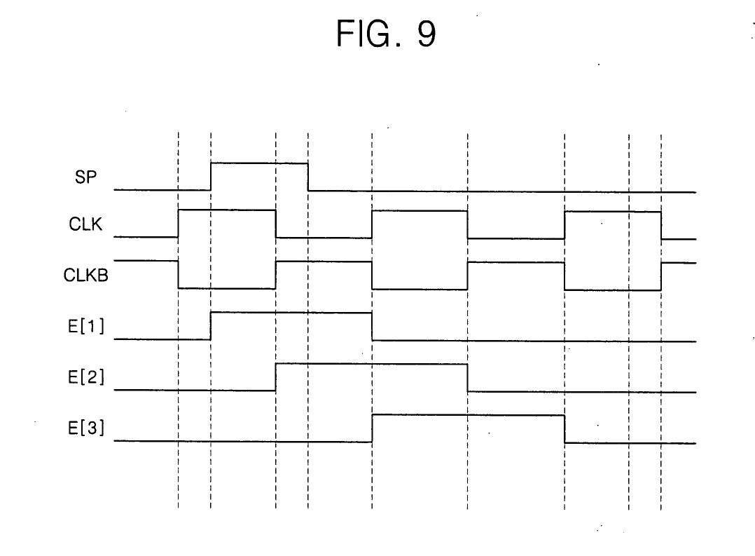

FIG. 9 is a timing diagram illustrating the operation of an emission control driver according to an embodiment. The operation of the emission control driver of FIGS. 7 and 8 will now be described with reference to FIG. 9. First, a high-level start pulse SP, a clock signal CLK, and an inverted clock signal CLKB are supplied to a first emission control driving circuit.

The first emission control driving circuit outputs to the pixel portion 100 a first emission control signal E1 that is kept at a high level from a rising edge of the start pulse SP to a rising edge of the clock signal CLK.

A second emission control driving circuit receives a flip flop output signal F1 of the first emission control driving circuit and receives the clock signal CLK and the inverted clock signal CLKB. The clock signal CLK and the inverted clock signal CLKB are supplied inversely to the first emission control driving circuit. The second emission control driving circuit samples the first emission control signal E1 on a falling edge of the clock signal CLK (a rising edge of the inverted clock signal) and outputs a second emission control signal E2 that is kept at a high level during one clock cycle to the pixel portion 100. The first emission control signal E1 and the second emission control signal E2 have a waveform in which a point at which a high level drops to a low level is shifted by half a clock cycle. Successive emission control driving circuits receive the preceding flip flop output signal Fn−1 to sequentially supply an emission control signal En shifted by half a clock cycle to the pixel portion 100.

The emission control driver 300 may operate using the clock signals and the start pulse independent of the scan driver 200 to independently adjust the duty cycle of the emission control signal En for luminance adjustment.

According to the embodiments described above, the scan driver for the organic light emitting display device is designed using a latch unit and a NAND gate instead of a shift register, thereby reducing the area occupied by the driver and thus can save space for a display panel. In addition, since the scan driver uses only the clock signal and the start pulse to generate a scan signal, the number of driving lines and transistors is reduced and cost and power losses are optimized.

Although certain embodiments have been described with reference to the attached drawings, changes may be made to the embodiments without departing from the scope of the invention.

What is claimed is:

1. A scan driver comprising a plurality of scan signal generating circuits configured to output a plurality of scan signals, the plurality of the scan signal generating circuits comprising a first scan signal generating circuit which comprises:
a first latch unit comprising a first input, a second input, and an output, the first input being configured to receive an immediately preceding scan signal, the second input being configured to receive an immediately succeeding scan signal; and
a first NAND gate comprising a first input, a second input, and an output, the first input being connected to the output of the first latch unit, the second input being configured to receive a first clock signal, the output being configured to output a first scan signal.

2. The scan driver of claim 1, wherein the plurality of scan signal generating circuits comprise odd-numbered scan signal generating circuits and even-numbered scan signal generating circuit, the odd-numbered scan signal generating circuits being configured to receive one of two clock signals having a phase difference of half a cycle, the even-numbered scan signal generating circuits being configured to receive the other of the two clock signals, and wherein the first scan signal generating circuit is one of the odd or even-numbered circuits.

3. The scan driver of claim 1, wherein the plurality of scan signal generating circuits further comprise a second scan signal generating circuit, and wherein the second scan signal generating circuit comprises:
a second latch unit comprising a first input, a second input, and an output, the first input being connected to the output of the first NAND gate, the second input being configured to receive an immediately succeeding scan signal; and
a second NAND gate comprising a first input, a second input, and an output, the first input being connected to the output of the second latch unit, the second input being configured to receive a second clock signal, the second clock signal having a phase difference of half a cycle with respect to the first clock signal, the output being connected to the second input of the first latch unit, the output being configured to output a second scan signal.

4. The scan driver of claim 1, wherein the first latch unit comprises:
an input unit configured to receive the immediately preceding scan signal and the immediately succeeding scan signal and to selectively output a positive power supply voltage to the output of the first latch unit depending on the scan signals; and
a negative voltage transmission unit configured to receive the positive power supply voltage from the input unit and to selectively output a negative power supply voltage to the output of the first latch unit depending on the scan signals.

5. The scan driver of claim 4, wherein the input unit comprises:
a first transistor having a source connected to a positive power supply source, a drain connected to the output of the first latch unit, and a gate connected to the first input of the first latch unit; and
a second transistor having a source connected to the positive power supply source, a drain connected to the negative voltage transmission unit, and a gate connected to the second input of the first latch unit.

6. The scan driver of claim 5, wherein the negative voltage transmission unit comprises:
a third transistor having a source connected to a negative power supply source, a drain connected to the drain of the second transistor, and a gate connected to the drain of the first transistor; and
a fourth transistor having a source connected to the negative power supply source, a drain connected to the drain of the first transistor, and a gate connected to the drain of the second transistor.

7. The scan driver of claim 6, wherein the first and second transistors have a different conductivity type from that of the third and fourth transistors.

8. The scan driver of claim 1, wherein the NAND gate comprises:
a positive voltage transmission unit configured to selectively output a scan signal having a positive power supply voltage level depending on an output signal of the first latch unit and the first clock signal; and
a negative voltage transmission unit configured to selectively output a scan signal having a negative power supply voltage level depending on the output signal of the first latch unit and the first clock signal.

9. The scan driver of claim 8, wherein the positive voltage transmission unit comprises two transistors connected in parallel between a positive power supply voltage source and the output of the first NAND gate, one of the transistors having a gate connected to the output of the first latch unit, the other of the transistors having a gate configured to receive the first clock signal; and
wherein the negative voltage transmission unit comprises two transistors connected in series between a negative power supply voltage source and the output of the first NAND gate, one of the transistors having a gate connected to the output of the first latch unit, the other of the transistors having a gate configured to receive the first clock signal.

10. The scan driver of claim 9, wherein the transistors of the positive voltage transmission unit have a conductivity type different from that of the transistors of the negative voltage transmission unit.

11. The scan driver of claim 1, wherein the first scan signal generating circuit further comprises a buffer unit having an input connected to the output of the first NAND gate and an output configured to supply the first scan signal.

12. A display device comprising the scan driver of claim 1.

13. The display device of claim 12, wherein the display device comprises an organic light emitting display device.

14. The display device of claim 12, further comprising:
an array of pixels; and
an emission control driver configured to supply an emission control signal to the pixels,
wherein the scan driver is configured to supply the plurality of scan signals to the pixels.

15. A scan driver comprising a plurality of scan signal generating circuits configured to output a plurality of scan signals, the plurality of the scan signal generating circuits comprising: a first scan signal generating circuit configured to generate a first scan signal; a second scan signal generating circuit configured to generate a second scan signal; and a third scan signal generating circuit configured to generate a third scan signal, wherein the second scan signal generating circuit comprises:
means for receiving the first scan signal and the third scan signal and generating a second output signal such that the second output signal has a high-level from a falling edge of the first scan signal to a falling edge of the third scan signal; and
means for logically combining the second output signal and one of two clock signals having a phase difference of half a cycle, thereby generating the second scan signal.

16. The scan driver of claim 15, wherein the first scan signal, the second scan signal, and the third scan signal are sequentially output.

17. The scan driver of claim 15, wherein the first scan signal generating circuit comprises:
means for receiving a start pulse signal and the second scan signal and generating a first output signal such that the first output signal has a high-level from a falling edge of the start pulse signal to a falling edge of the second scan signal; and
means for conducting a NAND operation on the first output signal and the other of the two clock signals, thereby generating the first scan signal.

18. The scan driver of claim 15, wherein the plurality of the scan signal generating circuits comprise a fourth scan signal generating circuit configured to generate a fourth scan signal, and wherein the third scan signal generating circuit comprises:
means for receiving the second scan signal and the fourth scan signal and generating a third output signal such that the third output signal has a high-level from a falling edge of the second scan signal to a falling edge of the fourth scan signal; and
means for conducting a NAND operation on the third output signal and the other of the two clock signals, thereby generating the third scan signal.

19. A display device comprising the scan driver of claim 15.

20. A method of generating a plurality of scan signals for a display device, the method comprising:
generating a first scan signal;
generating a second scan signal; and
generating a third scan signal,
wherein generating the second scan signal comprises:
receiving the first scan signal and the third scan signal;
generating a second output signal based on the first scan signal and the third scan signal such that the second output signal has a high-level from a falling edge of the first scan signal to a falling edge of the third scan signal;
conducting a NAND operation on the second output signal and one of two clock signals having a phase difference of half a cycle, thereby generating the second scan signal.

21. The method of claim 20, wherein generating the third scan signal comprises:
receiving the second scan signal and an immediately succeeding scan signal;
generating a third output signal based on the second scan signal and the immediately succeeding scan signal such that the third output signal has a high-level from a falling edge of the second scan signal to a falling edge of the immediately succeeding scan signal;
conducting a NAND operation on the third output signal and the other of the two clock signals, thereby generating the third scan signal.
